(19) United States
(12) Patent Application Publication
(10) Pub. No.: US 2020/0166829 A1
(43) Pub. Date: May 28, 2020

(54) PROJECTION SYSTEM AND PROJECTION SETTING METHOD THEREOF

(71) Applicant: Coretronic Corporation, Hsin-Chu (TW)

(72) Inventor: Hsin-Ya Lai, Hsin-Chu (TW)

(73) Assignee: Coretronic Corporation, Hsin-Chu (TW)

(21) Appl. No.: 16/691,447

(22) Filed: Nov. 21, 2019

(30) Foreign Application Priority Data
Nov. 26, 2018 (CN) 201811414677.4

(51) Int. Cl. G03B 21/26; G03F 7/20

(52) U.S. Cl. CPC G03B 21/26; G03F 7/70258

(57) ABSTRACT

A projection system having projection devices and an electronic device is provided. The projection devices respectively project an image, and each projection device is connected to and communicates with each other. The electronic device is connected to and communicates with the projection devices. A projection setting method of the projection system is also provided, and the projection setting method includes inspecting projection devices by an electronic device and identifying a main projection device from the projection devices. The electronic device is connected to an application program interface of the main projection device and transmits at least one setting command to the main projection device. The main projection device controls at least one corresponding projection device according to the setting command, so that the corresponding projection device is operated according to the setting command.

### CROSS-REFERENCE TO RELATED APPLICATION

This application claims the priority benefit of China application serial no. 201811414677.4, filed on Nov. 26, 2018. The entirety of the above-mentioned patent application is hereby incorporated by reference herein and made a part of this specification.

### BACKGROUND OF THE INVENTION

### Field of the Invention

The invention relates to a control technology; more particularly, the invention relates to a projection system and a projection setting method of the projection system.

### Description of Related Art

High-end projectors have been widely used in commercial fields and can be seen in exhibition halls, restaurants, etc. To support the complex functions of the high-end projectors, when setting up the high-end projectors, it is necessary to construct a computer that controls the high-level projectors and a central control room to flexibly control various functions of the high-end projectors. However, the needs required by the exhibition halls are changed quickly. The positions and the number of the high-end projectors often change with the different exhibitions halls. At this time, a user also needs to re-adjust the connection between the high-end projectors and the central control computer and the related settings. In addition, some projection systems require the purchase of a costly control box as a projection medium between the computers and the high-end projectors. Therefore, the design of the central control room and the control box increases the manpower and construction costs of the projection system.

Moreover, if the user intends to control the high-end projectors, he or she must go to the central control room to adjust the projection settings of the high-end projectors. The space of normal exhibition halls is quite large, and thus it is time-consuming and tiring for the user to go to the central control room. In another aspect, since the central control computer must send control signals to the high-end projectors according to the set schedule, the central control computer and the high-end projectors must be continuously connected to transmit the control signals in real time. Accordingly, people skilled in the pertinent art are endeavored to learn how to improve the adjustment of the projection system and its control mode for facilitating the user's control of the projectors and at the same time reducing the construction costs and the labor costs.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be solved by one or more embodiments of the invention was acknowledged by people of ordinary skill in the pertinent art.

### SUMMARY OF THE INVENTION

The invention provides a projection system and a projection setting method to provide users a more flexible and cost-effective way to set up a projection device.

Other advantages can be further illustrated by the technical features broadly embodied and described as follows.

To achieve one, part, or all of the foregoing purposes or other purposes, an embodiment of the invention provides a projection system. The projection system has a plurality of projection devices and an electronic device. The projection devices are configured to respectively project an image, and each of the projection devices is connected to and communicates with each other. The electronic device is connected to and communicates with the projection device s. The electronic device inspects the projection devices and identifies a main projection device from the projection devices. The electronic device is connected to an application program interface of the main projection device and transmits at least one setting command to the main projection device. The main projection device controls at least one corresponding projection device of the projection devices according to the at least one setting command, so as to enable the at least one corresponding projection device to perform an operation according to the at least one setting command.

To achieve one, part, or all of the foregoing purposes or other purposes, an embodiment of the invention provides a projection setting method. The projection setting method is suitable for a projection system that has a plurality of projection devices and an electronic device. The projection setting method includes following steps. The projection devices are inspected by the electronic device, and a main projection device is identified from the projection devices. An application program interface of the main projection device is connected by the electronic device, and at least one setting command is transmitted to the main projection device. At least one corresponding projection device of the projection devices is controlled by the main projection device according to the at least one setting command, so that the at least one corresponding projection device is operated according to the at least one setting command.

In view of the above, according to the projection system and the projection setting method provided herein, one of the projection devices is configured to serve as the main projection device, and the main projection device is connected to the electronic device and can thus set up the projection devices. This can be considered as a mobile central control station. It is no longer necessary for the projection system to be equipped with any control box. As such, the labor costs and the costs of equipment can be effectively reduced.

Other objectives, features and advantages of the invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic system view of a projection system according to an embodiment of the invention.

FIG. 2 is a schematic view of a structure of a projection system according to an embodiment of the invention.

FIG. 3 schematically illustrates a flowchart of a projection setting method according to an embodiment of the invention.

FIG. 4 is a schematic view of connections of a projection system according to an embodiment of the invention.

### DETAILED DESCRIPTION OF EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

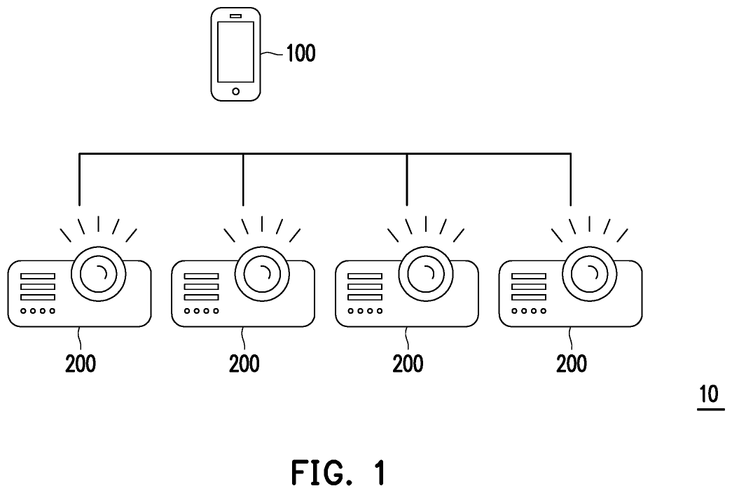

FIG. 1 is a schematic system view of a projection system according to an embodiment of the invention. With reference to FIG. 1, a projection system 10 has an electronic device 100 and a plurality of projection devices 200. The electronic device 100 communicates with and is connected to the projection devices 200 through a cable or in a wireless (e.g., Bluetooth, WIFI, etc.) manner. In an embodiment of the invention, the electronic device 100 and the projection devices 200 are in the same domain, which is not limited to be an internal domain or an external domain. For instance, if the electronic device 100 is connected to four individual projection devices 200, Internet protocol (IP) addresses of the projection devices 200 include but are not limited to 192.168.0.100-192.168.0.103.

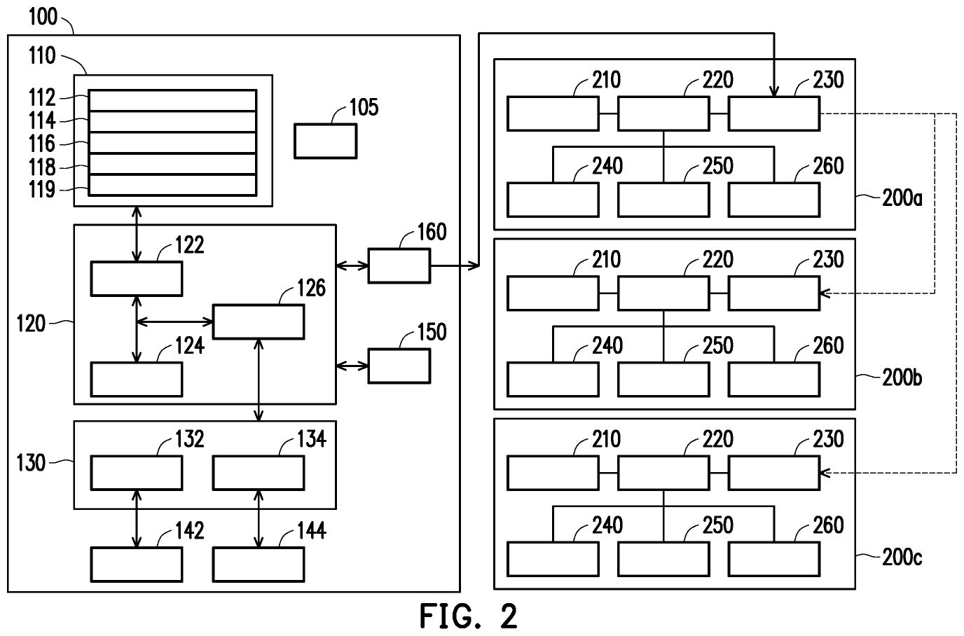

FIG. 2 is a schematic view of a structure of a projection system according to an embodiment of the invention. With reference to FIG. 2, the electronic device 100 has a power supply system 105, a storage unit 110, a control chip 120, a read-and-write subsystem 130, a touch screen 142, another input control device 144, an external device interface 150, and a radio-frequency (RF) circuit 160.

The power supply system 105 is configured to provide electric power required by the entire electronic device 100. For instance, the power supply system 105 in form of a charger battery may provide the electric power to all elements within the electronic device 100, and the invention is not limited thereto.

The storage unit 110 is configured to store modules and information required for running the electronic device 100, and the modules and information include but are not limited to an operation system 112 for running the electronic device 100, a communication module 114, a touch moving module 116, a drawing module 118, necessary programming codes of various application programs 119, and so on. In an embodiment of the invention, the storage unit 110 includes but is not limited to one or a combination of a read only memory (ROM), a flash memory, and a solid state hardware (SSD) drive.

The control chip 120 is connected to the storage unit 110 and has a storage unit controller 122, a central processor 124, and a peripheral interface controller 126. The storage unit controller 122 is connected to the storage unit 110 and configured to visit the storage unit 110 to access the programming codes and information required by various elements of the electronic device 100. The storage unit controller 122 is implemented in form of a corresponding control chip, and the invention is not limited thereto. The central processor 124 is connected to the storage unit controller 122 and configured to run computations required by the electronic device 100 and process various type of data. The central processor 124 is implemented in form of a processing chip with sufficient computation capabilities, and the type of the central processor 124 is not limited herein. The peripheral interface controller 126 is connected to the storage unit controller 122 and the central processor 124 and configured to receive signals from the peripheral interface and transmit the signals to the central processor 124 for data computations. The peripheral interface controller 126 includes but is not limited to a controller supporting an external drive.

The read-and-write subsystem 130 is connected to the control chip 120 and has a touch screen controller 132 and another input controller 134. The touch screen controller 132 is connected to the touch screen 142 to receive the touch information inspected by the touch screen 142. Besides, the touch screen controller 132 also control the information displayed by the touch screen 142. The read-and-write subsystem 130 can also have another input controller 134 corresponding to another input control device 144, so as to control another input control device. The touch screen controller 132 and the input controller 134 are implemented in form of various types of corresponding chips, and the invention is not limited thereto.

The external device interface 150 is connected to the control chip 120. The external device interface 150 is an interface configured to connect external elements (e.g., an earphone, an external portable drive, etc.), so as to receive signals from or output signals to the control chip 120. The external device interface 150 can be operated together with different types of hardware in response to the type of the interface connected to the external device interface 150, and the invention is not limited thereto.

The RF circuit 160 is connected to the control chip 120, so as to convert the electric signals generated by the control chip 120 into electromagnetic waves or convert the received electromagnetic waves into electric signals and transmit the electric signals to the control chip 120. Thereby, the signals can be transmitted to the projection devices 200 and other equipment in the communication network through the electromagnetic waves. In an embodiment of the invention, the signal transmission manner supported by the RF circuit 160 includes but is not limited to Bluetooth, WIFI, and the like. Besides, the RF circuit 160 and other equipment can together constitute local area network.

The electronic device 100 may be implemented in form of any device having said elements and includes but is not limited to a smart phone, a wearable electronic device, a tablet computer, a personal digital assistant (PDA), a notebook computer, or any other portable electronic device that can be individually operated; however, the invention is not limited thereto.

The projection devices 200a, 200b, and 200c are configured to project images respectively. In an embodiment of the invention, each of the projection devices 200a, 200b, and 200c has an input device 210, a processing unit 220, a communication unit 230, an excitation light source driving unit 240, a projection lens adjusting unit 250, and a fan driving unit 260.

The input devices 210 are configured to allow users to input commands to the projection devices 200a, 200b, and 200c. For instance, the input devices 210 of the projection devices 200a, 200b, and 200c include but are not limited to infrared remote controllers or keyboards placed on the external casings of the projection devices 200a, 200b, and 200c.

The processing unit 220 is connected to the input device 210 and configured to process various types of signals received by the projection devices 200a, 200b, and 200c and control corresponding actuating elements according to the signals. The processing unit 220 is, for instance, a micro-processing unit (MCU) and may be implemented in form of various types of processing chips; the invention is not limited thereto.

The communication unit 230 is connected to the processing unit 220 and configured to receive signals from the outside of the projection devices 200a-200c and transmit the signals to the processing unit 220 for signal processing. The communication unit 230 is, for instance, a communication chip supporting RS485, RS232, or other cabled communication interfaces; alternatively, the communication unit 230 may be a communication ship supporting Bluetooth, WIFI, or other wireless communication interfaces. However, the type of the communication unit 230 is not limited in the invention, and any communication chip supporting the standard regulated by the Institute of Electrical and Electrons Engineers (IEEE) is applicable herein. After the processing unit 220 receives the signals received by the communication unit 230, the processing unit 220 controls the corresponding actuating elements according to the received signals. Note that the projection devices 200a, 200b, and 200c are communicated through the communication units 230 for information transmission in the same domain.

The excitation light source driving unit 240, the projection lens adjusting unit 250, and the fan driving unit 260 are respectively connected to the processing unit 220, so as to receive the control signal transmitted by the processing unit 220 and to be actuated. For instance, the excitation light source driving unit 240 controls an excitation light source (not shown) to excite a laser beam according to the control signal. The projection lens adjusting unit 250 adjusts a focal length of a projection lens (not shown) and a projection location of the projection lens according to the control signal. The fan driving unit 260 drives at least one fan (not shown) to be rotated according to the control signal. The excitation light source driving unit 240, the projection lens adjusting unit 250, and the fan driving unit 260 are implemented in form of corresponding types of controllers, which should not be construed as a limitation to the invention. Besides, in the present embodiment, the projection devices 200a-200c may be equipped with more elements or chips for controlling or adjusting the existing elements in response to actual needs, and the invention is not limited thereto.

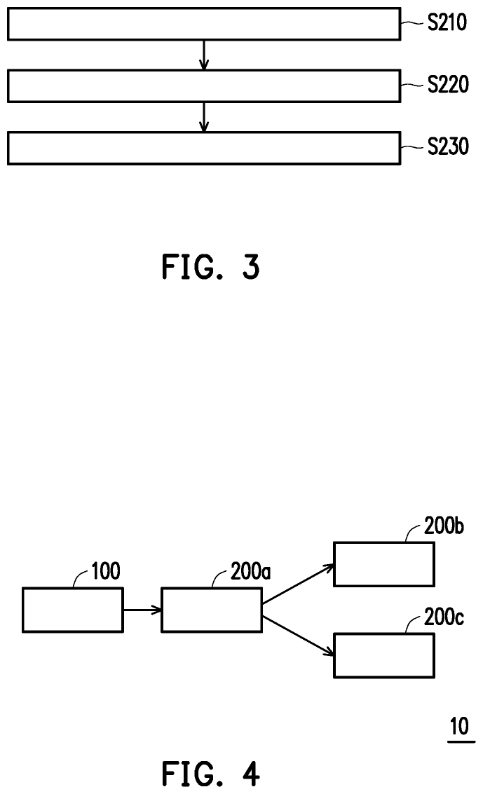

FIG. 3 schematically illustrates a flowchart of a projection setting method according to an embodiment of the invention. With reference to FIG. 3, the projection setting method is at least applicable to the projection system 10 depicted in FIG. 1 and FIG. 2, but the invention is not limited thereto. How the projection setting method is conducted in the projection system 10 is described below with reference to FIG. 1 and FIG. 2. Before the projection setting method is conducted, note that corresponding application programs are installed in the electronic device 100, so as to send information to the projection devices 200a, 200b, and 200c through the application programs. In the following descriptions, the operation performed by the application programs of the electronic device 100 will be represented as the electronic device 100.

In step S210, the electronic device 100 inspects the projection devices 200a, 200b, and 200c and identifies a main projection device from the projection devices 200a, 200b, and 200c. According to the embodiment, the projection devices 200a, 200b, and 200c respectively correspond to different IP addresses, and the IP addresses corresponding to the projection devices 200a, 200b, and 200c are in the same domain. For instance, the projection devices 200a, 200b, and 200c are in the same local area network, and for example, the IP addresses are 192.168.0.100, 192.168.0.101, and 192.168.0.102, respectively.

When any one of the projection devices 200a, 200b, and 200c is booted up, broadcast information is periodically sent to the network, so as to inspect other projection devices 200a, 200b, and 200c in the domain and update a device list corresponding to the projection devices 200a, 200b, and 200c. Note that the “booted up” process in the embodiment at least includes the state in which the non-activated communication units 230 of the projection devices 200a, 200b, and 200c are activated. At this time, the processing unit 220 may be in an activation state or in a hibernation state, and the invention is not limited thereto.

The electronic device 100 further obtains a device list corresponding to the projection devices 200a, 200b, and 200c transmitted from the projection devices 200a, 200b, and 200c and determines whether the corresponding main projection device already exists in the projection devices 200a, 200b, and 200c.

In another embodiment of the invention, the electronic device 100 may also receive the IP address input by a user, so as to search the projection devices 200a, 200b, and 200c at this IP address. For instance, if the communication protocol adopted by the projection devices 200a, 200b, and 200c does not support the automatic identification of other projection devices in the same domain, the projection devices 200a, 200b, and 200c are unable to inspect the projection devices 200a, 200b, and 200c in the same domain through sending the broadcast information. At this time, the user is able to search for the projection devices 200a, 200b, and 200c through inputting the IP address at the electronic device 100.

Further, the electronic device 100 determines whether the corresponding main projection device exists in the projection devices 200a, 200b, and 200c. In the embodiment, if the electronic device 100 is unable to identify the main projection device from the projection devices 200a, 200b, and 200c, the electronic device 100 spontaneously selects one of the projection devices 200a, 200b, and 200c as the main projection device. Alternatively, the electronic device 100 may receive a main projection device setting command input by the user, so as to set one of the projection devices corresponding to the main projection device setting command as the main projection device.

FIG. 4 is a schematic view of connections of a projection system according to an embodiment of the invention. With reference to FIG. 4, in the embodiment and the following explanations, the projection device 200a serves as the main projection device; however, the invention is not limited thereto. After the main projection device 200a is completely set, the communication relationship of the projection system 10 is substantially the same as that depicted in FIG. 4; that is, the electronic device 100 communicates and exchanges information with the main projection device 200a, and the main projection device 200a exchanges information with the controlled projection devices 200b and 200c.

As shown in FIG. 3, in step S220, the electronic device 100 is connected to an application program interface of the corresponding main projection device 200a and transmits a setting command to the main projection device 200a.

In an embodiment of the invention, the application program interface of the corresponding main projection device 200a is displayed in form of a web page, for instance. The electronic device 100 may transmit the setting command to the main projection device 200a through connecting the web page. Alternatively, the main projection device 200a provides the electronic device 100 with the device management interface of the corresponding projection devices 200b, 200c and the main projection device 200a, so that the electronic device 100 respectively transmits the setting command corresponding to the projection devices 200b, 200c and the setting command corresponding to the main projection device 200a to the main projection device 200a. Particularly, the device management interface provides the current status of each of the projection devices 200a, 200b, and 200c, and the user is able to browse the status of the main projection device 200a and the status of each of the projection devices 200b, 200c through connecting the main projection device 200a by the electronic device 100, so as to accordingly adjust the setting command. Moreover, the projection devices 200b, 200c also transmit the corresponding operating status to the main projection device 200a, so that the main projection device 200a updates the status information of the corresponding projection devices 200a, 200b, and 200c in the device management interface and updates the status of the main projection device 200a itself. In an embodiment of the invention, the electronic device 100 is connected to the main projection device 200a through, for instance, artnet, crecerme, pj-link, telnet, SNMP extrem, or a web page; however, the invention is not limited thereto.

The setting command is configured to control the schedule of the projection devices 200a, 200b, and 200c. According to the embodiment, the setting command includes a setting schedule and setting conditions; however, the invention is not limited thereto. The setting schedule is the designated time at which the projection devices 200a, 200b, and 200c perform various functions. The setting conditions are the functions designated to be performed by the projection devices 200a, 200b, and 200c, and the setting conditions include but are not limited to booting and shutdown, picture-in-picture (PIP) settings, auto-corrections, and so on. For instance, the setting conditions may be, “booting up at 10 a.m.” or “updating firmware at 1 a.m.”.

In an embodiment of the invention, the number of setting commands may be one or more and respectively correspond to the projection devices 200a, 200b, and 200c. The setting commands may be the same or different. That is, the electronic device 100 may transmit the same setting command to the main projection device 200a and the projection devices 200b and 200c through the main projection device 200a at the same time or transmit different setting commands to the main projection device 200a or one or more of the projection devices 200b, 200c at the same time. For instance, the electronic device 100 may transmit the setting command of “booting up at 10 a.m.” to the projection device 200a and the projection device 200b, and transmit the setting command of “updating firmware at 1 a.m.” to the projection device 200b.

In step S230, the main projection device 200a controls at least one corresponding projection device of the projection devices 200b and 200c and/or the main projection device 200a itself according to the setting command, so as to enable the at least one of the projection devices 200b, 200c and the main projection device 200a to project images according to the setting command.

Particularly, in an embodiment of the invention, the main projection device 200a sends the corresponding setting conditions to at least one of the projection devices 200b, 200c according to the setting schedule, so as to enable at least one of the projection devices 200b, 200c to be operated according to the setting conditions. The above-mentioned examples are applied for further explanation here. After the main projection device 200a receives the setting command of “booting up at 10 a.m.” to the projection device 200a and the projection device 200b from the electronic device 100″ and the setting command of “updating firmware at 1 a.m.” to the projection device 200b, the main projection device 200a starts the command of activating a computation function and transmits the command of activating the computation function to the projection device 200b. Besides, the main projection device 200a also transmits the setting command of updating firmware to the projection device 200b at 1 a.m. Accordingly, the projection devices 200a and 200b are operated according to the setting command, so as to perform functions corresponding to the setting command.

In another embodiment of the invention, after receiving the setting command, the main projection device 200a transmits at least one setting command to at least one of the projection devices 200b and 200c, so that the at least one of the projection devices 200b and 200c is operated according to the setting schedule and the setting conditions. Namely, according to the embodiment, the main projection device 200a neither controls nor manages its own schedule and the schedule of the projection devices 200b, 200c. The above-mentioned examples are applied for further explanation here. After the main projection device 200a receives the setting command of “booting up at 10 a.m.” to itself and the projection device 200b and the setting command of “updating firmware at 1 a.m.” to the projection device 200b, the main projection device 200a directly sends the setting command to its communication unit and to the projection device 200b. According to the received command, the projection devices 200a and 200b are booted up at 10 a.m. The main projection device 200a also transmits the setting command of updating the firmware to the projection device 200b, and the projection device 200b automatically updates the firmware at 1 a.m.

In an embodiment of the invention, note that when the main projection device 200a controls itself and the corresponding projection devices 200b, 200c according to at least one setting command, the processing unit 220 of the main projection device 200a and the processing units 220 of the controlled projection devices 200b and 200c are in a hibernation state. Besides, the communication unit 230 of the main projection device 200a and the communication units 230 of the controlled projection devices 200b and 200c are in a non-hibernation state. The communication units 230 of the projection devices 200b and 200c wake up the corresponding processing units 220 according to at least one setting command, so as to allow the processing units 220 to project images according to at least one setting command. Note that in the hibernation state it is determined whether the elements are normally operated by charging the processing units 220 and the communication units 230.

The above-mentioned examples are again applied for explanation here. When the main projection device 200a transmits the setting command of “booting up at 10 a.m.” to the projection device 200a and the projection device 200b, the processing unit 220 of the main projection device 200a and the processing unit 220 of the controlled projection device 200b are in the hibernation state, and the communication units 230 are in the non-hibernation state. At 10 a.m., according to the setting command, the communication units 230 wake up the corresponding processing unit 220 and start the computation function. Namely, the projection devices 200a and 200b receiving the setting command can still complete the projection setting method while only the communication units 230 can perform the communication function.

To sum up, according to the projection system and the projection setting method provided herein, one of the projection devices is configured to serve as the main projection device, and the main projection device is connected to the electronic device and can thus set up the projection devices. This can be considered as a mobile central control station. As such, the human resources required for adjusting the projection devices can be saved. Since it is no longer necessary for the projection system to additionally arrange the central control room or control box in each place, the costs of equipment can be reduced. Moreover, the main projection device and the projection devices in the hibernation state can still perform the setting function through the communication units in the non-hibernation state. Since the main projection device and the projection devices need not be continuously connected for the setting purposes, the consumption of resources can be reduced.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims. The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A projection system comprising a plurality of projection devices and an electronic device, wherein
the projection devices are configured to respectively project an image, each of the projection devices communicates with and is connected to each other, and
the electronic device communicates with and is connected to the projection devices,
wherein the electronic device inspects the projection devices and identifies a main projection device from the projection devices,
the electronic device is connected to an application program interface of the main projection device and transmits at least one setting command to the main projection device, and
the main projection device controls at least one corresponding projection device of the projection devices according to the at least one setting command, so as to enable the at least one corresponding projection device to be operated according to the at least one setting command.

2. The projection system according to claim 1, wherein the electronic device spontaneously selects one of the plurality of projection devices as the main projection device when the electronic device is unable to identify the main projection device from the projection devices, or
the electronic device receives the at least one main projection device setting command and sets one of the projection devices corresponding to the at least one main projection device setting command as the main projection device when the electronic device is unable to identify the main projection device from the projection devices.

3. The projection system according to claim 1, wherein the at least one setting command comprises a setting schedule and setting conditions corresponding to the setting schedule, and the main projection device sends the corresponding setting conditions to at least one of the projection devices according to the setting schedule, so as to enable the at least one of the projection devices to be operated according to the setting conditions.

4. The projection system according to claim 1, wherein the at least one setting command comprises a setting schedule and setting conditions corresponding to the setting schedule, and the main projection device sends the at least one setting command to at least one of the projection devices, so as to enable the at least one of the projection devices to be operated according to the setting schedule and the setting conditions.

5. The projection system according to claim 1, wherein the projection devices respectively correspond to different Internet protocol addresses, and the Internet protocol addresses corresponding to the projection devices are in a same domain.

6. The projection system according to claim 5, wherein the projection devices periodically detect the projection devices in the domain, so as to update a device list corresponding to the projection devices.

7. The projection system according to claim 1, wherein the application program interface of the main projection device provides a device management interface corresponding to the projection devices to the electronic device, so that the electronic device respectively transmits each of the at least one setting command corresponding to the projection devices to the main projection device.

8. The projection system according to claim 7, wherein the projection devices further respectively transmit a corresponding operating status to the main projection device, so that the main projection device updates status information corresponding to the projection devices in the device management interface.

9. The projection system according to claim 1, wherein each of the projection devices comprises a communication unit and a processing unit, and the communication unit is electrically connected to the processing unit,
wherein when the main projection device controls the at least one corresponding projection device according to the at least one setting command, the processing unit of the main projection device and the processing unit of the controlled projection device are in a hibernation state,
and the communication unit of the main projection device and the communication unit of the controlled projection device are in a non-hibernation state,
wherein the communication unit of at least one of the projection devices wakes up the corresponding processing unit according to the at least one setting command, so that the processing unit projects the image according to the at least one setting command.

10. The projection system according to claim 1, wherein the number of the at least one setting command is plural, and the setting commands respectively correspond to the projection devices, wherein the setting commands are the same or different setting commands.

11. A projection setting method suitable for a projection system, the projection system comprising a plurality of projection devices and an electronic device, the projection setting method comprising:
inspecting the projection devices by the electronic device and identifying a main projection device from the projection devices;
connecting an application program interface of the main projection device and transmitting at least one setting command to the main projection device by the electronic device; and
controlling at least one corresponding projection device of the projection devices according to the at least one setting command by the main projection device, so as to enable the at least one corresponding projection device to perform an operation according to the at least one setting command.

12. The projection setting method according to claim 11, wherein the step of inspecting the projection devices by the electronic device and identifying the main projection devices from the projection devices further comprises:
spontaneously selecting one of the projection devices as the main projection device by the electronic device when no main projection device is identified from the projection devices, or
receiving at least one main projection device setting command of and setting one of the projection devices corresponding to the at least one main projection device setting command as the main projection device by the electronic device when no main projection device is identified from the projection devices.

13. The projection setting method according to claim 11, wherein the at least one setting command comprises a setting schedule and setting conditions corresponding to the setting schedule, and the step of controlling the at least one corresponding projection device of the projection devices according to the at least one setting command by the main projection device to enable the at least one corresponding projection device to perform an operation according to the at least one setting command further comprises:
sending the corresponding setting conditions to at least one of the projection devices according to the setting schedule by the main projection device;
performing the operation, by at least one of the projection devices, according to the setting conditions.

14. The projection setting method according to claim 11, wherein the at least one setting command comprises a setting schedule and setting conditions corresponding to the setting schedule, and the step of controlling the at least one corresponding projection device of the projection devices according to the at least one setting command by the main projection device to enable the at least one corresponding projection device to project according to the at least one setting command further comprises:
transmitting the at least one setting command by the main projection device to at least one of the projection devices; and
operating the at least one of the projection devices according to the setting schedule and the setting conditions.

15. The projection setting method according to claim 14, further comprising:
transmitting a corresponding operating status to the main projection device by the projection devices; and
updating status information corresponding to the projection devices in the device management interface by the main projection device.

16. The projection setting method according to claim 11, wherein the projection devices respectively correspond to different Internet protocol addresses, the Internet protocol addresses corresponding to the projection devices are in a same domain, and the projection setting method further comprises:
periodically inspecting the projection devices in the domain by the projection devices, so as to update a device list corresponding to the projection devices.

17. The projection setting method according to claim 11, further comprising:
providing a device management interface corresponding to the projection devices to the electronic device by the main projection device, so that the electronic device respectively transmits each of the at least one setting command corresponding to the projection devices to the main projection device.

18. The projection setting method according to claim 11, wherein when the main projection device controls the at least one corresponding projection device of the projection devices according to the at least one setting command, each of the projection devices comprises a communication unit and a processing unit, the communication unit is electrically connected to the processing unit, the processing unit of the main projection device and the processing unit of the controlled projection device are in a hibernation state, and the communication unit of the main projection device and the communication unit of the controlled projection device are in a non-hibernation state,
wherein the step of controlling the at least one corresponding projection device of the projection devices according to the at least one setting command by the main projection device, so as to enable the at least one corresponding projection device to be operated according to the at least one setting command further comprises:
waking up the corresponding processing unit according to the at least one setting command by the communication unit of at least one of the projection devices; and
projecting an image according to the at least one setting command by the processing unit.

19. The projection setting method according to claim 11, wherein the number of the at least one setting command is plural, and the setting commands respectively correspond to the projection devices, wherein the setting commands are the same or different setting commands.
